(19) United States
(12) Patent Application Publication
(10) Pub. No.: US 2013/0285164 A1
(43) Pub. Date: Oct. 31, 2013

(54) MEMS DEVICE AND METHOD OF MANUFACTURING THE SAME

(71) Applicant: KABUSHIKI KAISHA TOSHIBA, Tokyo (JP)

(72) Inventors: Tomohiro SAITO, Yokohama-shi (JP); Yohei SYUHAMA, Kitakami-shi (JP)

(73) Assignee: KABUSHIKI KAISHA TOSHIBA, Tokyo (JP)

(21) Appl. No.: 13/839,600

(22) Filed: Mar. 15, 2013

(30) Foreign Application Priority Data
Apr. 27, 2012 (JP) 2012-103646

(51) Int. Cl. B81B 3/00; B81C 1/00

(52) U.S. Cl. CPC B81B 3/0018; B81C 1/00134
USPC 257/415; 438/50

(57) ABSTRACT

According to one embodiment, a MEMS device comprises a first electrode fixed on a substrate, a second electrode formed above the first electrode to face the first electrode, and vertically movable, a second anchor portion formed on the substrate and configured to support the second electrode, and a second spring portion configured to connect the second electrode and the second anchor portion. The second spring portion is continuously formed from an upper surface of the second electrode to an upper surface of the second anchor portion, and has a flat lower surface.

### CROSS-REFERENCE TO RELATED APPLICATIONS

This application is based upon and claims the benefit of priority from Japanese Patent Application No. 2012-103646, filed Apr. 27, 2012, the entire contents of which are incorporated herein by reference.

### FIELD

Embodiments described herein relate generally to a MEMS device and a method of manufacturing the same.

### BACKGROUND

A Micro-Electro-Mechanical Systems (MEMS) device formed by a movable electrode and fixed electrode is attracting attention as a key device of next-generation cell phones because the device has a low loss, high insulation properties, and high linearity. Therefore, it is desirable to use a low-resistance metal material such as aluminum (Al) in electrode portions.

The MEMS device, however, has the feature that it is necessary to vertically drive the electrode structure. Al or the like used as the movable electrode is a ductile material. When the movable electrode is repetitively driven, therefore, the initial structure cannot be held any longer due to a creep phenomenon (a shape change caused by stress). On the other hand, it is also possible to use a material such as tungsten (W) having plastic deformation smaller than that of Al as the movable electrode. However, W is unfavorable because it has a high resistance value and this spoils a low resistance as the characteristic of the MEMS.

To solve the above-mentioned problem, a method of using a brittle material as a spring portion for connecting the movable electrode made of a ductile material and a support portion (anchor portion) for supporting the movable electrode has been proposed. In this method, the spring portion connected to the movable electrode is made of a brittle material. Even when the movable electrode is driven, therefore, no creep phenomenon occurs, and no deformation from the initial structure occurs for a long time.

Unfortunately, the spring portion made of a brittle material is formed, after the movable electrode and anchor portion are formed, so as to cover a step portion between the movable electrode and a sacrificial layer that finally forms a hollow portion, and a step portion between the sacrificial layer and anchor portion. The film quality of the spring portion (brittle material) formed on these step portions deteriorates. In particular, the film quality of a bent portion of the spring portion positioned on the step portion deteriorates. This makes the etching rate of the brittle material formed on the step portion higher than that of the brittle material formed on flat portions (the upper surfaces of the sacrificial layer, movable electrode, and anchor portion). Consequently, the brittle material on the step portion is cut when the spring portion is processed. Even if the material is not cut, it is narrowed, and this decreases the durability during repetitive driving.

### BRIEF DESCRIPTION OF THE DRAWINGS

FIG. 1 is a plan view showing the structure of a MEMS device according to an embodiment;

FIG. 2 is a sectional view showing the structure of the MEMS device according to the embodiment;

FIGS. 3, 4, 5, 6, 7, 8, and 9 are sectional views showing the manufacturing steps of the MEMS device according to the embodiment;

FIGS. 10 and 11 are enlarged plan views showing the manufacturing steps of the MEMS device according to the embodiment; and

FIGS. 12 and 13 are enlarged plan views showing modifications of the manufacturing steps of the MEMS device according to the embodiment.

### DETAILED DESCRIPTION

In general, according to one embodiment, a MEMS device comprises: a first electrode fixed on a substrate; a second electrode formed above the first electrode to face the first electrode, and vertically movable; a second anchor portion formed on the substrate and configured to support the second electrode; and a second spring portion configured to connect the second electrode and the second anchor portion. The second spring portion is continuously formed from an upper surface of the second electrode to an upper surface of the second anchor portion, and has a flat lower surface.

This embodiment will be explained below with reference to the accompanying drawing. In the drawing, the same reference numerals denote the same parts. Also, a repetitive explanation will be made as needed.

### Embodiment

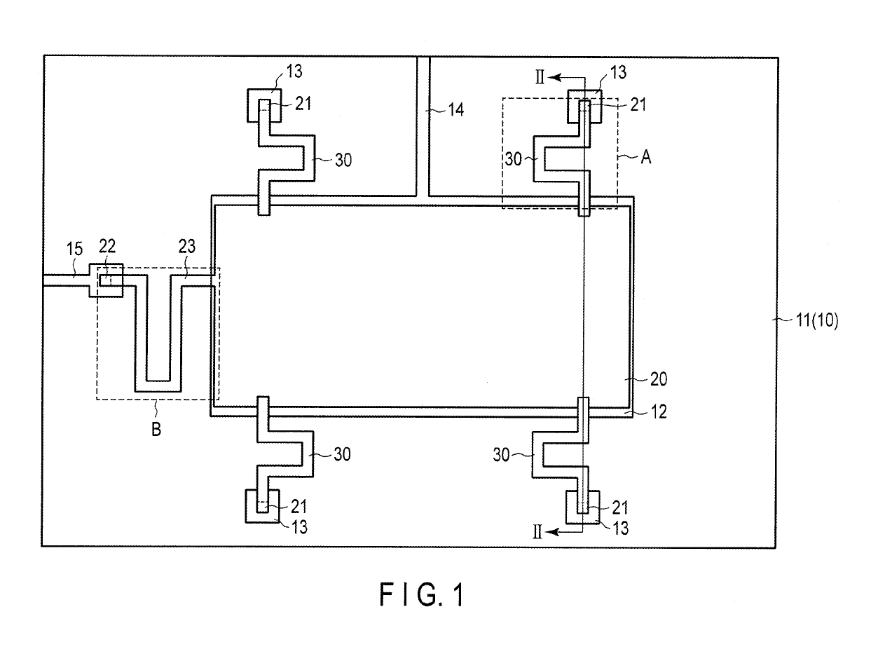

The MEMS device according to this embodiment will be explained with reference to FIGS. 1, 2, 3, 4, 5, 6, 7, 8, 9, 10, 11, 12, and 13. In this embodiment, a second spring portion 30 for connecting an upper electrode 20 and second anchor portion 21 is continuously formed from the upper surface of the upper electrode 20 to the upper surface of the second anchor portion 21, and horizontally formed with no step between them. Accordingly, the second spring portion 30 having a shape with desired characteristics can be formed in the MEMS device. Details of this embodiment will be explained below.

### [Structure]

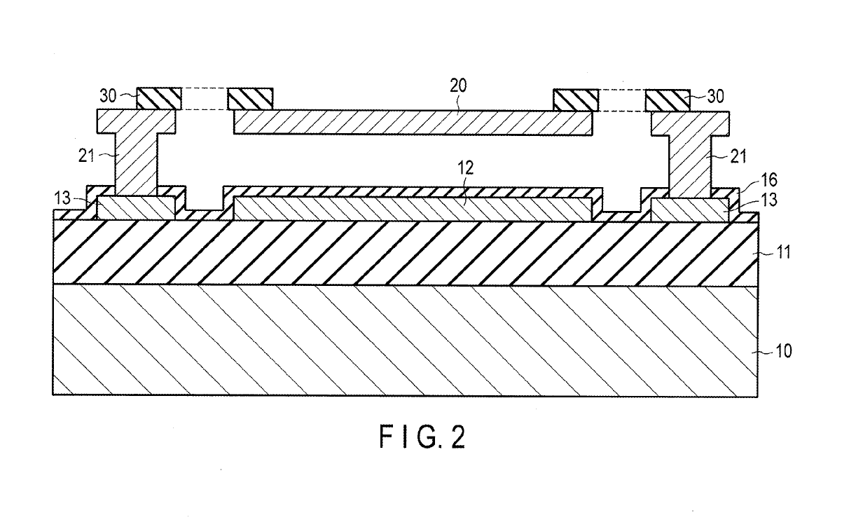

First, the structure of the MEMS device according to this embodiment will be explained with reference to FIGS. 1 and 2.

FIG. 1 is a plan view showing the structure of the MEMS device according to this embodiment. FIG. 2 is a sectional view taken along a line A-A in FIG. 1, and showing the structure of the MEMS device according to this embodiment.

As shown in FIGS. 1 and 2, the MEMS device according to this embodiment includes a lower electrode 12 formed on an interlayer dielectric layer 11 on a support substrate 10, and an upper electrode 20.

The support substrate 10 is, e.g., a silicon substrate. The interlayer dielectric layer 11 is desirably made of a low-k material in order to decrease the parasitic capacitance. The interlayer dielectric layer 11 is made of, e.g., silicon oxide (SiOₓ) formed by using SiH₄ or TEOS (Tetra Ethyl Ortho Silicate) as a material. Also, the film thickness of the interlayer dielectric layer 11 is desirably large in order to decrease the parasitic capacitance. For example, the film thickness of the interlayer dielectric layer 11 is desirably 10 μm or more.

Elements such as field-effect transistors can be formed on the surface of the support substrate 10. These elements form a logic circuit and memory circuit. The interlayer dielectric layer 11 is formed on the support substrate 10 so as to cover these circuits. Therefore, the MEMS device is formed above the circuits on the support substrate 10.

Note that a circuit such as an oscillator that can generate noise is desirably not formed below the MEMS device. It is also possible to form a shield metal in the interlayer dielectric layer 11, and prevent the propagation of noise from the lower circuits to the MEMS device. Furthermore, an insulating substrate such as a glass substrate may also be used instead of the support substrate 10 and interlayer dielectric layer 11. In the following explanation, the support substrate 10 and interlayer dielectric layer 11 will be referred to as a substrate in some cases.

The lower electrode 12 is formed on the substrate and fixed on it. The lower electrode 12 has, e.g., a plate shape parallel to the surface of the substrate. The lower electrode 12 is made of, e.g., Al (aluminum), an alloy containing Al as a main component, Cu (copper), Au (gold), or Pt (platinum). The lower electrode 12 is connected to an interconnection 14 made of the same material as that of the lower electrode 12, and connected to various circuits via the interconnection 14. An insulating layer 16 made of, e.g., SiOₓ, silicon nitride (SiN), or a high-k material is formed on the surface of the lower electrode 12.

The upper electrode 20 is formed above the lower electrode 12, supported in the air, and vertically movable (in a direction perpendicular to the substrate). The upper electrode 20 has a plate shape parallel to the substrate surface, and is arranged to face the lower electrode 12. That is, the upper electrode 20 overlaps the lower electrode 12 in a plane (a plane parallel to the substrate surface; this plane will simply be referred to as a plane hereinafter) spreading in a first direction (the horizontal direction in FIG. 1) and a second direction (the vertical direction in FIG. 1) perpendicular to the first direction. The upper electrode 20 is made of, e.g., Al, an alloy containing Al as a main component, Cu, Au, or Pt. That is, the upper electrode 20 is made of a ductile material. The ductile material has the feature that when destroying a member made of the ductile material by applying stress to the member, the member is destroyed after causing a large plastic change (extension).

Note that the planar shape of each of the lower electrode 12 and upper electrode 20 is a rectangle in the drawing, but it is not limited to a rectangle and may also be a square, circle, or ellipse. Note also that the area of the lower electrode 12 is larger than that of the upper electrode 20 in the plane, but the present embodiment is not limited to this.

A first spring portion 23 and a plurality of second spring portions 30 are connected to the movable upper electrode 20 supported in midair. The first spring portion 23 and second spring portions 30 are made of different materials.

The first spring portion 23 connects the upper electrode 20 and a first anchor portion 22 for supporting the upper electrode 20.

More specifically, one end of the first spring portion 23 is connected to one end (end portion) of the upper electrode 20 in the first direction. The first spring portion 23 is, e.g., formed to be integrated with the upper electrode 20. That is, the upper electrode 20 and first spring portion 23 have one continuous single-layered structure, and are formed on the same level. The first spring portion 23 has, e.g., a meander planar shape. In other words, the first spring portion 23 is formed long and narrow and has a meander shape in the plane.

The first spring portion 23 is made of, e.g., a conductive ductile material, and made of the same material as that of the upper electrode 20. That is, the first spring portion 23 is made of a metal material such as Al, an alloy containing Al as a main component, Cu, Au, or Pt.

The other end of the first spring portion 23 is connected to the first anchor portion 22. The first anchor portion 22 supports the upper electrode 20. The first anchor portion 22 is, e.g., formed to be integrated with the first spring portion 23. Therefore, the first anchor portion 22 is made of, e.g., a conductive ductile material, and made of the same material as that of the upper electrode 20 and first spring portion 23. For example, the first anchor portion 22 is made of Al, an alloy containing Al as a main component, Cu, Au, or Pt. Note that the first anchor portion 22 may also be made of a material different from that of the upper electrode 20 and first spring portion 23.

The first anchor portion 22 is formed on an interconnection 15. The interconnection 15 is formed on the interlayer dielectric layer 11. The surface of the interconnection 15 is covered with an insulating layer (not shown). This insulating layer is, e.g., formed to be integrated with the insulating layer 16. A hole is formed in this insulating layer, and the first anchor portion 22 is in direct contact with the interconnection 15 through this hole. That is, the upper electrode 20 is electrically connected to the interconnection 15 via the first spring portion 23 and first anchor portion 22, and connected to various circuits. Consequently, a potential (voltage) is applied to the upper electrode 20 via the interconnection 15, first anchor portion 22, and first spring portion 23.

The second spring portion 30 is connected to each of the four corners (the end portions in the first and second directions) of the rectangular upper electrode 20. Note that the four second spring portions 30 are formed in this embodiment, but the number is not limited to four. Each second spring portion 30 connects the upper electrode 20 and a second anchor portion 21 for supporting the upper electrode 20. Details of the second spring portion 30 according to this embodiment will be described later.

Each second anchor portion 21 is formed on a dummy layer 13. The second anchor portion 21 is made of, e.g., a conductive ductile material, and made of the same material as that of the upper electrode 20 and first spring portion 23. For example, the second anchor portion 21 is made of a metal material such as Al, an alloy containing Al as a main component, Cu, Au, or Pt. Note that the second anchor portion 21 may also be made of a material different from that of the upper electrode 20 and first spring portion 23.

The dummy layers 13 are formed on the interlayer dielectric layer 11. The surface of each dummy layer 13 is covered with, e.g., an insulating layer formed to be integrated with the insulating layer 16. A hole is formed in this insulating layer, and the second anchor portion 21 is in direct contact with the dummy layer 13 through this hole. Note that the second anchor portion 21 need not be in direct contact with the dummy layer 13.

Note that the interconnection 15 and dummy layer 13 are made of, e.g., the same material as that of the lower electrode 12. Note also that the film thickness of the interconnection 15 and dummy layer 13 is about the same as that of the lower electrode 12.

In this embodiment, the second spring portion 30 is continuously formed from the upper surface of the upper electrode 20 to the upper surface of the second anchor portion 21, and horizontally formed with no step between them. Note that the explanation will be made by taking the structure in the initial operation state of the MEMS device as an example.

More specifically, one end of the second spring portion 30 is formed on the upper electrode 20. Therefore, the second spring portion 30 is formed in contact with the upper surface of the upper electrode 20, and the connecting portion of the second spring portion 30 and upper electrode 20 has a multilayered structure. The other end of the second spring portion 30 is formed on the second anchor portion 21. Accordingly, the second spring portion 30 is formed in contact with the second anchor portion 21, and the connecting portion of the second spring portion 30 and second anchor portion 21 has a multilayered structure. The second anchor portion 21 supports the upper electrode 20.

The second spring portion 30 is in midair between the upper electrode 20 and second anchor portion 21. The second spring portion 30 is horizontally formed on the upper surface of the upper electrode 20, on the upper surface of the second anchor portion 21, and in the air. In other words, the lower surface of the second spring portion 30 is flat on the upper surface of the upper electrode 20, on the upper surface of the second anchor portion 21, and in the air. That is, since the upper surfaces of the upper electrode 20 and second anchor portion 21 are on the same level (at the same height), the second spring portion 30 is formed on the same level on the upper surface of the upper electrode 20, on the upper surface of the second anchor portion 21, and in midair. Therefore, the lower surface of the second spring portion 30 is on the same level as that of the upper surfaces of the upper electrode 20 and second anchor portion 21. In other words, the second spring portion 30 has no step in the interface between the upper surface of the upper electrode 20 and the midair portion, and in the interface between the upper surface of the second anchor portion 21 and the midair portion. Note that the second spring portion 30 can have not only a flat lower surface but also a flat upper surface. The second spring portion 30 has, e.g., a meander planar shape between the upper electrode 20 and second anchor portion 21.

Since the second spring portion 30 has the above-mentioned structure, it is possible to prevent the second spring portion 30 from being cut or narrowed, thereby preventing deterioration of the durability.

Note that the second spring portion 30 need only be generally horizontal on the upper surface of the upper electrode 20, on the upper surface of the second anchor portion 21, and in the air. This is so because a flexure or the like can form when setting the second spring portion 30 in midair in a process to be described later. That is, “horizontal” herein mentioned includes “nearly horizontal” by which the second spring portion 30 forms no step portion and does not deteriorate the film quality. Analogously, in the expression “the lower surface of the second spring portion 30 is “flat”, “flat” includes “nearly flat”.

The second spring portion 30 is made of, e.g., a brittle material. The brittle material has the feature that when destroying a member made of the brittle material by applying stress, the material is destroyed after causing almost no plastic change (shape change). Generally, energy (stress) required to destroy a member using the brittle material is smaller than that required to destroy a member using the ductile material. That is, a member using the brittle material is destroyed more easily than a member using the ductile material. Examples of the brittle material are SiOₓ, SiN, and silicon oxynitride (SiON).

A spring constant k2 of the second spring portion 30 using the brittle material is set larger than a spring constant k1 of the first spring portion 23 using the ductile material, by appropriately setting at least one of the line width of the second spring portion 30, the film thickness of the second spring portion 30, and the flexure of the second spring portion 30. Note that it is desirable to use SiN having a relatively large elastic constant as the brittle material of the second spring portion 30.

When the first spring portion 23 made of the ductile material and the second spring portions 30 made of the brittle material are connected to the movable upper electrode 20 as in this embodiment, the spring constant k2 of the second spring portions 30 using the brittle material practically determines the spacing between the capacitance electrodes in a state in which the upper electrode 20 is pulled up (this state will be referred to as an up-state hereinafter).

The second spring portion 30 made of the brittle material hardly causes a creep phenomenon. Even when the MEMS device is repetitively driven a plurality of times, therefore, the variation in spacing between the capacitance electrodes (the upper electrode 20 and lower electrode 12) is small in the up-state. Note that the creep phenomenon of a material is a change with time, or a phenomenon in which the distortion (shape change) of a given member increases when stress is applied to the member.

When the MEMS device is driven a plurality of times, the first spring portion 23 made of the ductile material causes the creep phenomenon. However, the spring constant k1 of the first spring portion 23 is set smaller than the spring constant k2 of the second spring portion 30 using the brittle material. Accordingly, the shape change (deflection) of the first spring portion 23 using the ductile material exerts no large influence on the spacing between the capacitance electrodes in the up-state.

In this embodiment, therefore, the conductive ductile material can be used as the movable upper electrode (movable structure) 20. That is, the loss of the MEMS device can be reduced because a low-resistivity material can be used as the movable upper electrode 20 without taking the creep phenomenon into consideration.

### [Manufacturing Method]

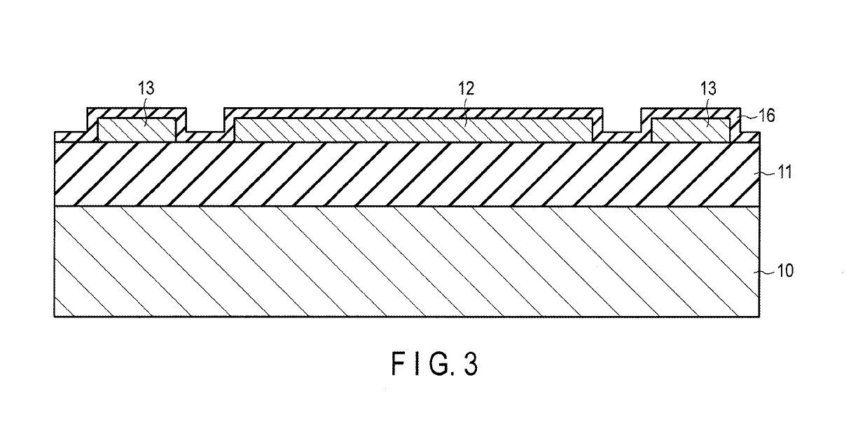

Next, a method of manufacturing the MEMS device according to this embodiment will be explained with reference to FIGS. 3, 4, 5, 6, 7, 8, 9, 10, and 11.

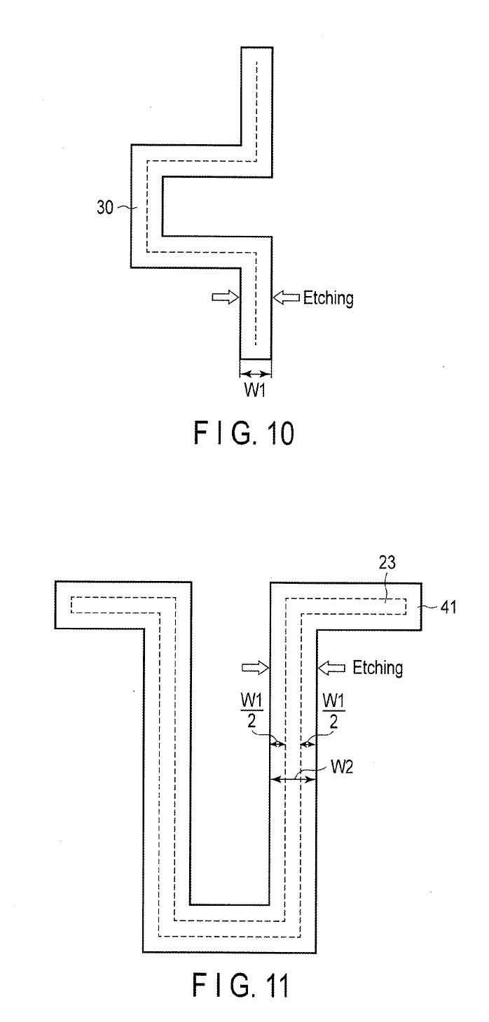

FIGS. 3, 4, 5, 6, 7, 8, and 9 are sectional views taken along a line II-II in FIG. 1, and showing the manufacturing steps of the MEMS device according to this embodiment. FIGS. 10 and 11 are enlarged plan views showing the manufacturing steps of the MEMS device according to this embodiment. More specifically, FIG. 10 is an enlarged view of a region A in FIG. 1, and FIG. 11 is an enlarged view of a region B in FIG. 1.

First, as shown in FIG. 3, an interlayer dielectric layer 11 is formed on a support substrate 10 by, e.g., P-CVD (Plasma Enhanced Chemical Vapor Deposition). The interlayer dielectric layer 11 is made of, e.g., SiOₓ formed by using SiH₄ or TEOS as a material. After that, a metal layer is evenly formed on the interlayer dielectric layer 11 by, e.g., sputtering. This metal layer is made of, e.g., Al, an alloy containing Al as a main component, Cu, Au, or Pt.

Then, the metal layer is patterned by, e.g., lithography and RIE (Reactive Ion Etching), thereby forming a lower electrode 12 on the interlayer dielectric layer 11. At the same time, dummy layers 13 and interconnections 14 and 15 are formed on the interlayer dielectric layer 11.

After that, an insulating layer 16 is formed on the entire surface by P-CVD or the like. Consequently, the surfaces of the lower electrode 12, dummy layers 13, and interconnections 14 and 15 are covered with the insulating layer 16. The insulating layer 16 is made of, e.g., SiOₓ, SiN, or a high-k material.

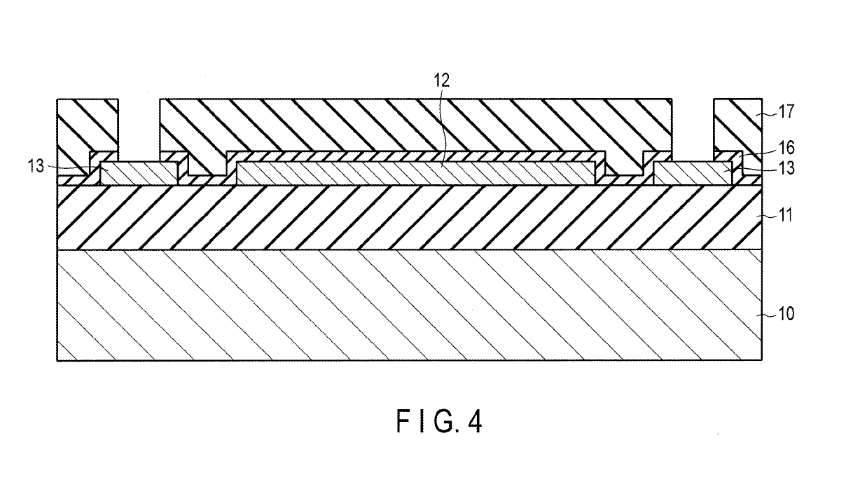

Subsequently, as shown in FIG. 4, the insulating layer 16 is coated with a sacrificial layer 17. The sacrificial layer 17 is made of an organic material such as polyimide. After that, the sacrificial layer 17 is patterned by, e.g., lithography and RIE, thereby partially exposing the insulating layer 16. The exposed insulating layer 16 is then etched by RIE or the like. Consequently, holes are formed in the sacrificial layer 17 and insulating layer 16 at the positions of portions where a first anchor portion 22 and second anchor portions 21 are to be formed (i.e., portions above the interconnection 15 and dummy layers 13), and the interconnection 15 and dummy layers 13 are exposed. Note that the dummy layers 13 need not be exposed in this step.

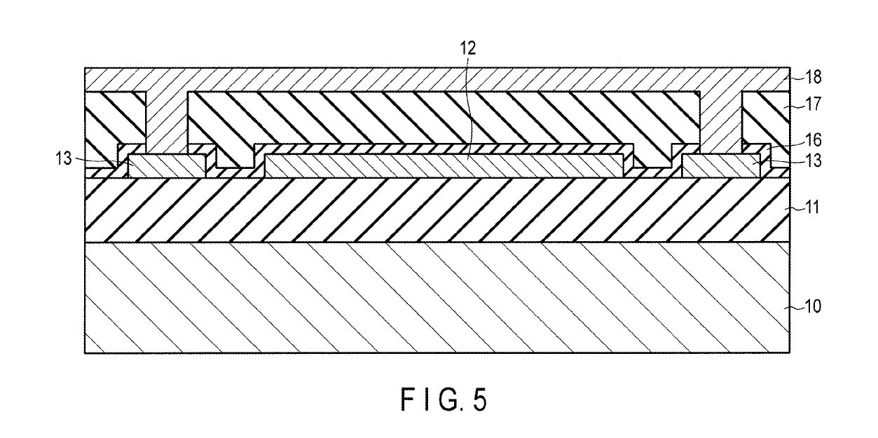

As shown in FIG. 5, a metal layer 18 is formed on the entire surface by sputtering or the like. More specifically, the metal layer 18 is formed on the upper surface of the sacrificial layer 17 outside the holes, and on the side surfaces of the sacrificial layer 17 (and insulating layer 16) inside the holes. That is, the metal layer 18 is so formed as to be buried in the holes. Consequently, the metal layer 18 is formed in contact with the interconnection 15 and dummy layer 13 on the bottom surface of each hole. The metal layer 18 is made of, e.g., Al, an alloy containing Al as a main component, Cu, Au, or Pt. The metal layer 18 is used to form an upper electrode 20, second anchor portions 21, a first anchor portion 22, and a first spring portion 23 in a later step.

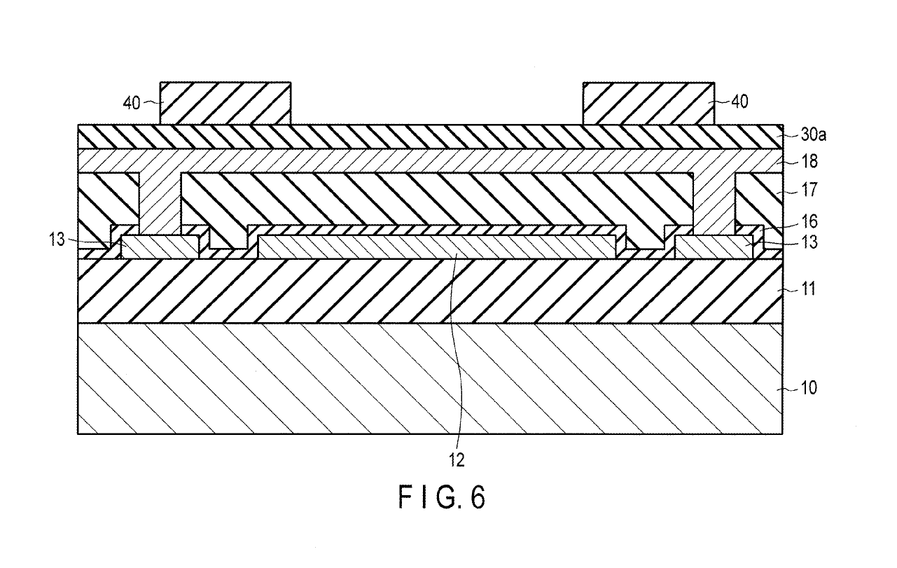

As shown in FIG. 6, a layer 30a to be used to form second spring portions 30 later is formed on the metal layer 18 by, e.g., P-CVD. The layer 30a is made of, e.g., a brittle material. Examples of the brittle material are SiOₓ, SiN, and SiON.

After that, a resist 40 is formed on the layer 30a and patterned by lithography or the like. As a consequence, resists 40 remain in prospective regions of second spring portions 30.

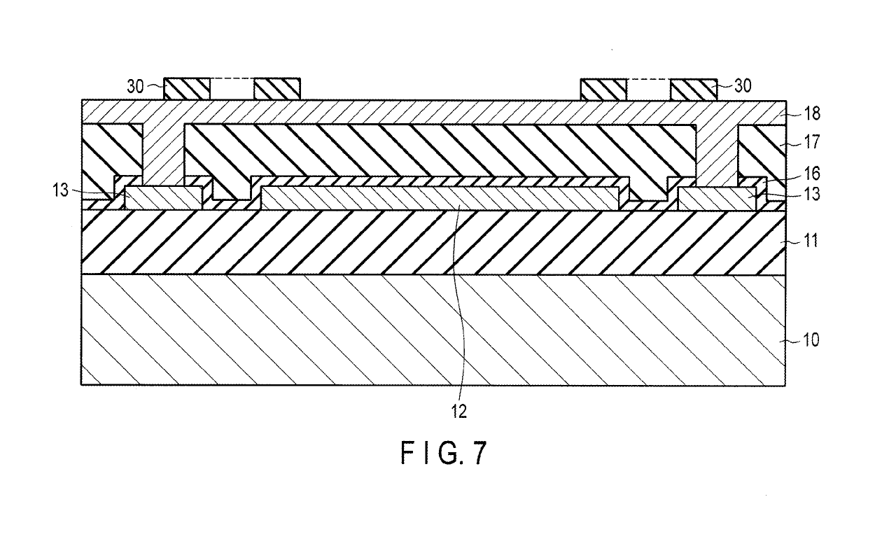

As shown in FIG. 7, the layer 30a made of the brittle material is etched by, e.g., RIE using the resists 40 as masks, thereby forming second spring portions 30 for connecting an upper electrode 20 and second anchor portions 21 to be formed later. In this step, the metal layer 18 to be used to form an upper electrode 20, second anchor portions 21, a first anchor portion 22, and a first spring portion 23 later is not processed but formed on the entire surface. Accordingly, the second spring portion 30 formed on the metal layer 18 is horizontally formed to have a predetermined film thickness without any step. In other words, the second spring portion 30 has a flat lower surface. Note that the second spring portion 30 can have not only a flat lower surface but also a flat upper surface.

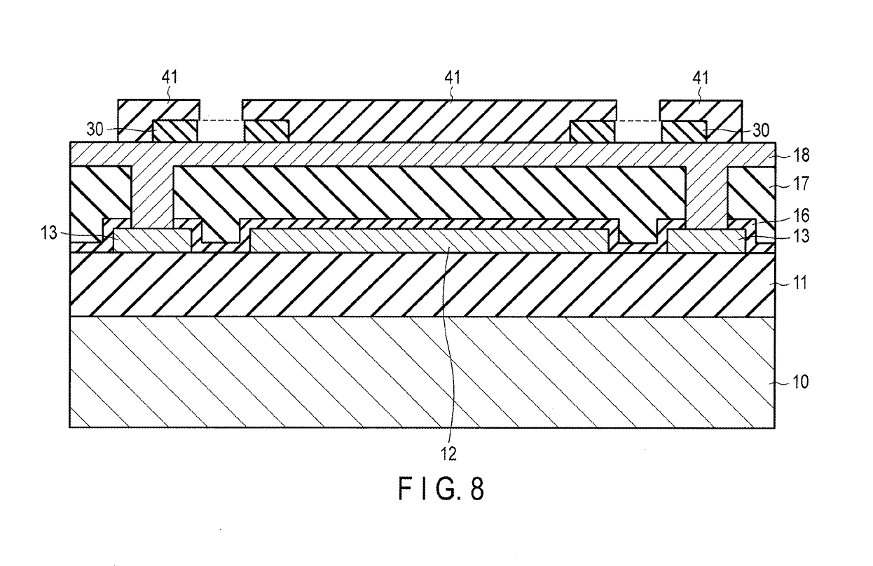

As shown in FIG. 8, a resist 41 is formed on the entire surface and patterned by lithography or the like. Consequently, resists 41 remain in prospective regions of an upper electrode 20, a first anchor portion 22, second anchor portions 21, and an interconnection 23. Note that the resists 41 are formed to be larger than the prospective regions of an upper electrode 20, a first anchor portion 22, second anchor portions 21, and an interconnection 23, because the metal layer 18 is isotropically etched as will be described below.

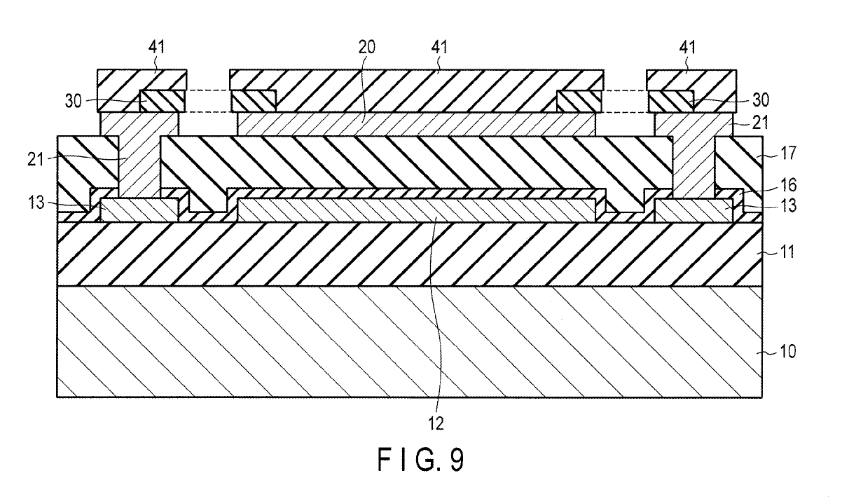

As shown in FIG. 9, the metal layer 18 is patterned by isotropic etching, e.g., wet etching. Consequently, an upper electrode 20 facing the lower electrode 12 is formed on the sacrificial layer 17. Also, second anchor portions 21 are formed on the dummy layers 13 in the holes. In addition, a first anchor portion 22 is formed on the interconnection 15 in the hole, and a first spring portion 23 for connecting the upper electrode 20 and first anchor portion 22 is formed on the sacrificial layer 17.

In this step, the metal layer 18 in a region except for the prospective regions of the upper electrode 20, second anchor portions 21, first anchor portion 22, and first spring portion 23 is unnecessary. That is, it is necessary to remove the metal layer 18 positioned below the second spring portions 30 (i.e., the metal layer 18 positioned behind the second spring portions 30). As described above, therefore, the metal layer 18 is etched not by anisotropic etching but by isotropic etching.

When performing isotropic etching, as shown in FIG. 10, the metal layer 18 positioned below the second spring portion 30 is etched from the sides. Therefore, to sufficiently remove the metal layer 18 positioned below the second spring portion 30, the etching amount of isotropic etching is set to be at least the half (W₁/2) of a width W₁ of the second spring portion 30.

On the other hand, as shown in FIG. 11, a metal layer pattern (e.g., the first spring portion 23) having the minimum width of the metal layer 18 is formed by forming the resist 41 on the metal layer 18 and etching the metal layer 18 from its sides by isotropic etching. In this step, the etching amount from each side of the first spring portion 23 is about the same as the etching amount (W₁/2) of the second spring portion 30. To form (leave) the first spring portion 23 (behind), therefore, a width W₂ of the resist 41 above the first spring portion 23 is set larger than the width W₁ of the second spring portion 30.

Note that before isotropic etching, the metal layer 18 may also be etched by anisotropic etching, e.g., RIE using the resists 41 and second spring portions 30 as masks. That is, after the metal layer 18 positioned in a portion except portions below the resists 41 and second spring portions 30 is removed by RIE, the metal layer 18 positioned below the second spring portions 30 is removed by isotropic etching. Generally, RIE (anisotropic etching) is controllable more easily than isotropic etching. By performing RIE in advance, therefore, it is possible to reduce the etching amount of isotropic etching, and improve the etching controllability.

Finally, as shown in FIG. 2, the resists 41 are removed, and the sacrificial layer 17 is removed by isotropic dry etching, e.g., O₂-based and Ar-based asking processes. Consequently, the first spring portion 23, second spring portions 30, and upper electrode 20 are set in midair. In other words, the movable region of the upper electrode 20 is formed between the lower electrode 12 and upper electrode 20 (below the upper electrode 20).

Note that a movable region must also be formed above the upper electrode 20 in practice. Since the movable region above the upper electrode 20 can be formed by various well-known methods, details of the formation method will be omitted.

For example, after the upper electrode 20, second anchor portions 21, first anchor portion 22, and first spring portion 23 are formed, a sacrificial layer (not shown) is formed on the upper electrode 20, first spring portion 23, second anchor portions 21, first anchor portion 22, and second spring portions 30, and an insulating layer (dome structure) (not shown) is formed on the sacrificial layer. After that, a through hole is formed in the insulating layer by patterning, and the sacrificial layer 17 and sacrificial layer (not shown) are simultaneously removed by isotropic dry etching, e.g., O₂-based and Ar-based asking processes. Consequently, the movable region of the upper electrode 20 is formed not only below the upper electrode 20 but also above the upper electrode 20.

Thus, the MEMS device according to this embodiment is formed.

### [Effects]

In the above-mentioned embodiment, the second spring portion 30 for connecting the upper electrode 20 and second anchor portion 21 is continuously formed from the upper surface of the upper electrode 20 to the upper surface of the second anchor portion 21, and horizontally formed with no step between them. That is, the second spring portion 30 is formed on the same level on the upper surface of the upper electrode 20, on the upper surface of the second anchor portion 21, and in midair. This makes it possible to prevent the second spring portion 30 from having a step portion and deteriorating the film quality. Accordingly, it is possible to prevent the second spring portion 30 from being cut or narrowed, thereby preventing deterioration of the durability. That is, the second spring portion 30 having a shape with desired characteristics can be formed in the MEMS device.

### [Modifications]

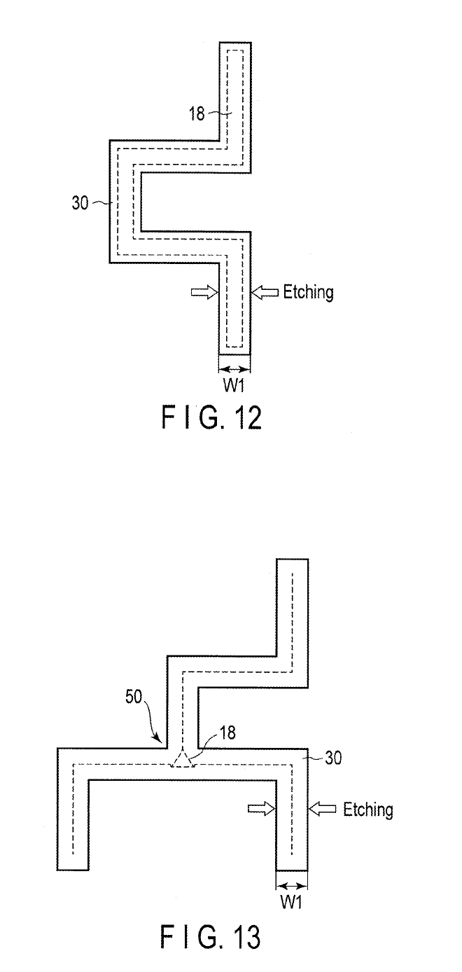

FIGS. 12 and 13 are enlarged plan views showing modifications of the manufacturing steps of the MEMS device according to this embodiment. More specifically, FIGS. 12 and 13 are enlarged views of the region A in FIG. 1.

As shown in FIG. 12, the metal layer 18 positioned below the second spring portion 30 may also be left behind in the step of pattering the metal layer 18 by isotropic etching. In other words, a multilayered structure of the second spring portion 30 (a brittle material) and the metal layer 18 (a ductile material) may also be formed as the spring portion. The metal layer 18 positioned below the second spring portion 30 is formed to be integrated with the upper electrode 20 and second anchor portion 21. In this multilayered structure, the upper electrode 20 and second anchor portion 21 can electrically be connected by the metal layer 18. This makes it possible to connect the upper electrode 20 to various circuits via the metal layer 18, second anchor portion 21, and dummy layer 13.

Also, as shown in FIG. 13, when the second spring portion 30 has a branched portion 50, the metal layer 18 positioned below the branched portion 50 of the second spring portion 30 may also be left behind in the step of patterning the metal layer 18 by isotropic etching, in order to reduce the increase in etching amount (etching time) of the metal layer 18. The metal layer 18 positioned below the branched portion 50 of the second spring portion 30 is hardly removed by isotropic etching compared to the metal layer 18 in other regions. When removing the metal layer 18 positioned below the branched portion 50, therefore, the etching amount becomes larger than that when the second spring portion 30 has no branched portion 50. By contrast, the increase in etching amount can be reduced by removing the metal layer 18 positioned in a region except for the branched portion 50, and leaving the metal layer 18 positioned below the branched portion 50 behind.

Note that the MEMS device according to this embodiment is not limited to the above-mentioned structure and manufacturing method.

In this embodiment, the second spring portion 30 made of a brittle material need not have a single-layered structure. For example, to improve the adhesion between the upper electrode 20 and second anchor portion 21, the second spring portion 30 may also have a multilayered structure including SiOₓ as a lower layer and SiN as an upper layer. In this case, the second spring portion 30 can be patterned by first etching the SiN layer and then etching the SiOₓ layer.

This embodiment can be applied to a method of driving the upper electrode 20 and lower electrode 12 by an electrostatic force by applying a voltage between them. However, this embodiment is also applicable to a method of forming the upper electrode 20 and lower electrode 12 as a multilayered structure of different metals, and driving the multilayered structure by its piezoelectric force.

This embodiment is applicable not only to a variable capacitance but also to a MEMS switch. In this case, the surface of the lower electrode 12 is exposed by etching away a portion of a capacitor insulating layer (the insulating layer 16) formed on the lower electrode 12, e.g., a portion in contact with the upper electrode 20. Consequently, a switch is formed by the upper electrode 20 and lower electrode 12, and operated by driving the upper electrode 20.

In this embodiment, the structure including the two electrodes, i.e., the movable upper electrode 20 and fixed lower electrode 12 has been explained. However, this embodiment is also applicable to a structure in which both the electrodes are movable, and a structure including three or more electrodes (e.g., a fixed upper electrode, fixed lower electrode, and movable middle electrode).

Furthermore, it is possible to appropriately set the areas of the upper electrode 20 and lower electrode 12 in the plane. It is also possible to form the MEMS structure including the upper electrode 20 and lower electrode 12 on a transistor circuit such as a CMOS. In addition, a dome structure covering and protecting the MESM structure can also be formed.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A MEMS device comprising:
a first electrode fixed on a substrate;
a second electrode formed above the first electrode to face the first electrode, and vertically movable;
a second anchor portion formed on the substrate and configured to support the second electrode; and
a second spring portion configured to connect the second electrode and the second anchor portion,
wherein the second spring portion is continuously formed from an upper surface of the second electrode to an upper surface of the second anchor portion, and has a flat lower surface.

2. The device of claim 1, wherein the second spring portion is made of a brittle material.

3. The device of claim 2, wherein the brittle material contains one material selected from the group consisting of SiOₓ, SiN, and SiON.

4. The device of claim 1, further comprising a metal layer formed below the second spring portion and configured to connect the second electrode and the second anchor portion.

5. The device of claim 4, wherein the metal layer is made of Al, an alloy containing Al as a main component, Cu, Au, or Pt.

6. The device of claim 4, wherein the metal layer is integrated with the second electrode and the second anchor portion.

7. The device of claim 1, further comprising a metal layer formed below the second spring portion,
wherein the second spring portion has a branched portion, and the metal layer is formed below the branched portion.

8. The device of claim 7, wherein the metal layer is made of Al, an alloy containing Al as a main component, Cu, Au, or Pt.

9. The device of claim 1, wherein a lower surface of the second spring portion is on the same level as that of upper surfaces of the second electrode and second anchor portion.

10. The device of claim 1, further comprising:
a first anchor portion formed on the substrate and configured to support the second electrode; and
a first spring portion configured to connect the second electrode and the first anchor portion.

11. The device of claim 10, wherein the first spring portion is made of a ductile material.

12. The device of claim 10, wherein a spring constant of the second spring portion is larger than that of the first spring portion.

13. A MEMS device manufacturing method comprising:
forming a fixed first electrode on a substrate;
forming a sacrificial layer on an entire surface;
forming a metal layer on the sacrificial layer;
forming a second spring portion on the metal layer; and
forming, by etching the metal layer, a second electrode and an anchor portion to be connected by the second spring portion.

14. The method of claim 13, further comprising forming a resist on the metal layer and patterning the resist before etching the metal layer,
wherein a width of the resist on a metal layer pattern having a minimum width formed by etching the metal layer is larger than a width of the second spring portion.

15. The method of claim 13, wherein the metal layer is etching by isotropic etching.

16. The method of claim 13, wherein the metal layer is etched by anisotropic etching and isotropic etching after the anisotropic etching.
